(19) United States
(12) Patent Application Publication
(10) Pub. No.: US 2024/0004183 A1
(43) Pub. Date: Jan. 4, 2024

(54) SCANNING MIRROR DEVICE

(71) Applicant: Microsoft Technology Licensing, LLC, Redmond, WA (US)

(72) Inventors: Risto Heikki MUTIKAINEN, Espoo (FI); Nikolai CHEKUROV, Helsinki (FI); Simo Kaarlo Tapani TAMMELA, Espoo (FI)

(73) Assignee: Microsoft Technology Licensing, LLC, Redmond, WA (US)

(21) Appl. No.: 17/809,779

(22) Filed: Jun. 29, 2022

(51) Int. Cl. G02B 26/08; G02B 26/10; G01S 17/894

(52) U.S. Cl. CPC G02B 26/0858; G02B 26/105; G01S 17/894

(57) ABSTRACT

A scanning mirror device comprises a mirror disposed on a mirror support. The scanning mirror device also includes a first pair of actuators comprising a first actuator and a second actuator. The first actuator is positioned on a first side of the mirror support. The second actuator is positioned on a second side of the mirror support opposite the first side of the mirror support. The first actuator and the second actuator are connected to the mirror support along a first axis of rotation. The scanning mirror device also includes a second pair of actuators comprising a third actuator and a fourth actuator. The third actuator is positioned on the first side of the mirror support. The fourth actuator is positioned on the second side of the mirror support. The third actuator and the fourth actuator are connected to the mirror support along a second axis of rotation.

### BACKGROUND

Scanning mirrors may be used in many types of optical devices. For example, a time-of-flight depth sensing system may utilize one or more micro electro-mechanical system (MEMS) mirrors to direct illumination light into an environment. The illumination light is used to produce a depth image of the environment, with each pixel of the depth image representing a distance to a corresponding point in the environment determined based on a round-trip time interval for the illumination light to reflect from the surface and return to an image sensor of the depth sensing system.

### SUMMARY

One example provides a scanning mirror device. The scanning mirror device comprises a mirror disposed on a mirror support. The scanning mirror device further comprises a first pair of actuators comprising a first actuator and a second actuator. The first actuator is positioned on a first side of the mirror support and the second actuator is positioned on a second side of the mirror support opposite the first side of the mirror support. The first actuator and the second actuator are connected to the mirror support along a first axis of rotation. The scanning mirror device further comprises a second pair of actuators comprising a third actuator and a fourth actuator. The third actuator is positioned on the first side of the mirror support and the fourth actuator is positioned on the second side of the mirror support. The first actuator and the second actuator are connected to the mirror support along a second axis of rotation.

Another example provides a scanning mirror device comprising a mirror disposed on a mirror support. A first actuator is connected to the mirror support at a first angle relative to the mirror support. A second actuator is connected to the mirror support at a second angle relative to the mirror support, and a third actuator is connected to the mirror support at a third angle relative to the mirror support.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 shows example electronic devices that may comprise scanning mirror devices.

FIG. 2 shows aspects of an example time-of-flight depth sensing system.

FIG. 3 shows an example scanning mirror device.

FIG. 4 shows another example scanning mirror device.

FIG. 5 shows yet another example scanning mirror device.

FIG. 6 shows an example of a time-of-flight projector device that may comprise a scanning mirror device according to the present disclosure.

FIG. 7 shows a block diagram of an example computing system.

### DETAILED DESCRIPTION

As introduced above, scanning mirrors may be used in a variety of electronic devices. For example, a depth camera, such as a time of flight (ToF) depth camera, may utilize one or more scanning mirrors to direct illumination light into an environment for acquiring a depth image.

In some instances, a scanning mirror system may comprise two mirrors that respectively rotate along transverse axes to scan light (e.g., in a Lissajous pattern). Utilizing separate mirrors for each axis of rotation may help to provide for stability and control, as the mirror may be constrained to prevent off-axis motion. However, systems that include two or more mirrors may be larger than systems based upon an individual mirror.

In other instances, one mirror may be mounted in a double-gimbal structure. The mirror is suspended within an inner gimbal, and the inner gimbal is nested within an outer gimbal. In this manner, the mirror can be controlled to scan the light in two or more directions. However, it may be challenging to control an orientation of the mirror in such an instance. Further, wires or other electrical conduits used to detect the orientation of the mirror and provide feedback to a controller may be prone to strain and breakage due to motion of the inner gimbal and the outer gimbal.

Accordingly, examples are disclosed that relate to a scanning mirror device in which a single mirror scans in two or more directions without the use of a double gimbal structure. Briefly, in the disclosed examples, two or more pairs of actuators are connected to a mirror support that supports a mirror. Each pair of actuators is operatively configured to tilt the mirror with respect to one of two or more different axes of rotation. This enables the mirror to controllably scan in different directions, for example to direct incident light in a raster pattern. Advantageously, the disclosed example actuators may be used to tilt the mirror to target orientations with or without optional use of strain gauges or other orientation sensors. For example, in a ToF depth camera, an image sensor forms a depth image of an illuminated environment using locating optics, so accurate direction of the light via the mirror may not be required. In addition, the disclosed example arrangements of actuators may enable the scanning mirror device to occupy less space than other scanning mirror devices (e.g., a double-gimbal device or a dual-mirror Lissajous scanning device).

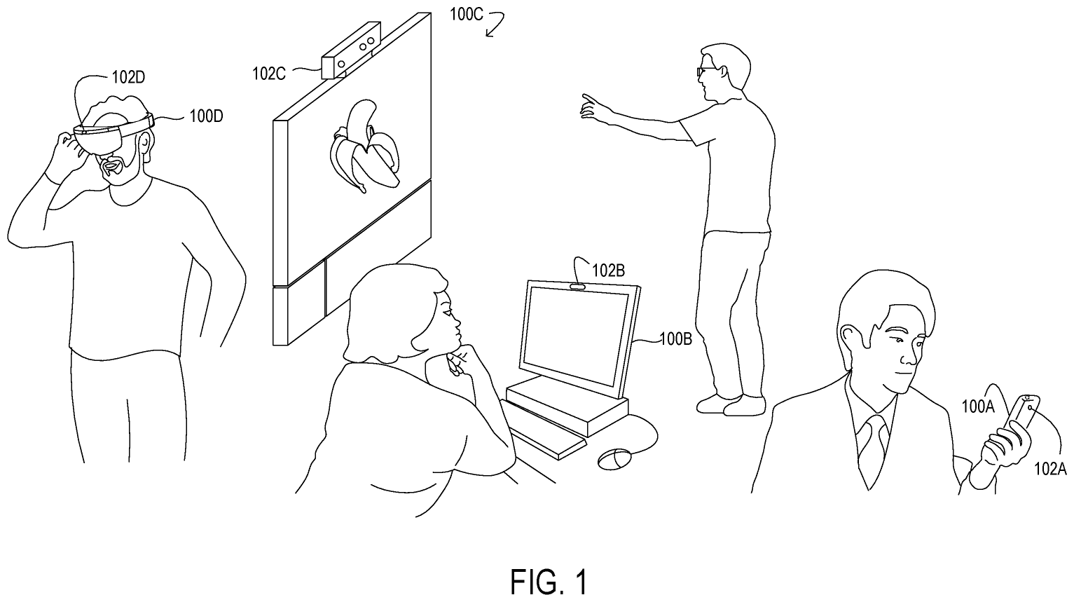

FIG. 1 illustrates various different example electronic devices 100A-E that may employ a scanning mirror device in a depth sensing system. Device 100A is a smartphone that includes a depth sensing system 102A. Device 100B is a personal computer that includes a depth-sensing web camera 102B. Device 100C is a video game system that includes a peripheral camera system comprising a depth sensing system 102C. Device 100D is a virtual-reality headset that includes a camera system comprising a depth sensing system 102D.

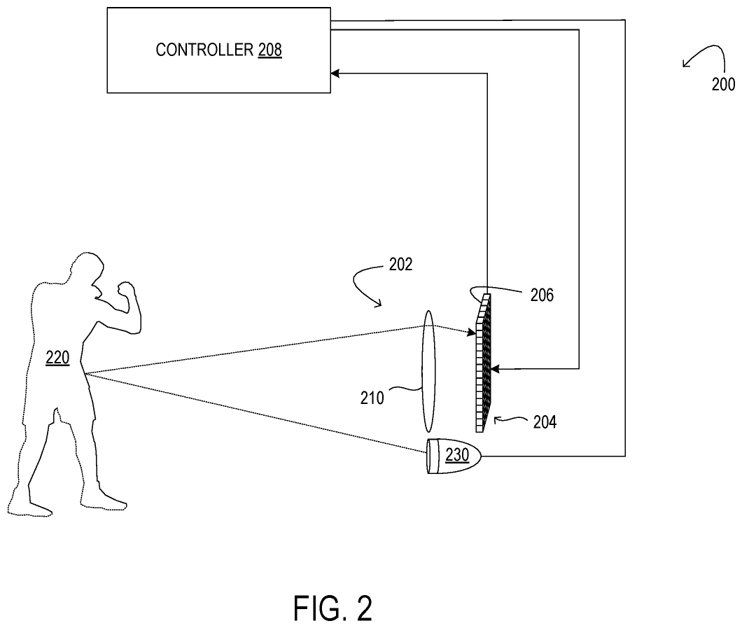

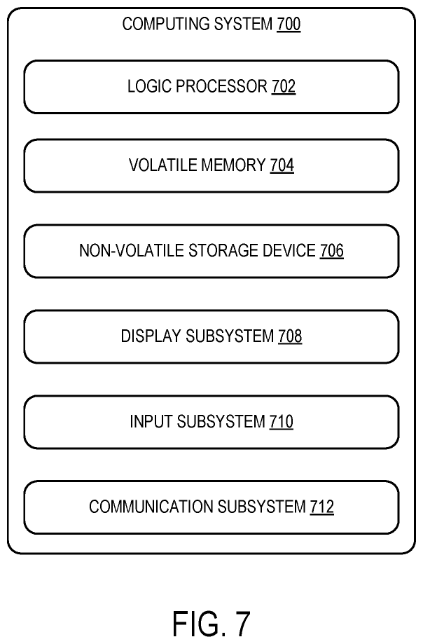

FIG. 2 shows a schematic depiction of an example time-of-flight (ToF) depth imaging system 200 that may utilize a scanning mirror system. The ToF depth imaging system includes a ToF camera 202. ToF camera 202 includes a sensor array 204 comprising a plurality of ToF pixels 206 each configured to acquire light samples, a controller 208, and an objective lens system 210 configured to focus an image of a subject 220 onto sensor array 204. In some examples, objective lens system 210 may be omitted. Controller 208 is configured to gather and process data from ToF pixels 206 of sensor array 204 and thereby construct a depth image. Examples of hardware implementations of computing devices configured to perform one or more aspects of gathering and processing data from the sensor array 204 and constructing the depth image are described in more detail below with reference to FIG. 7.

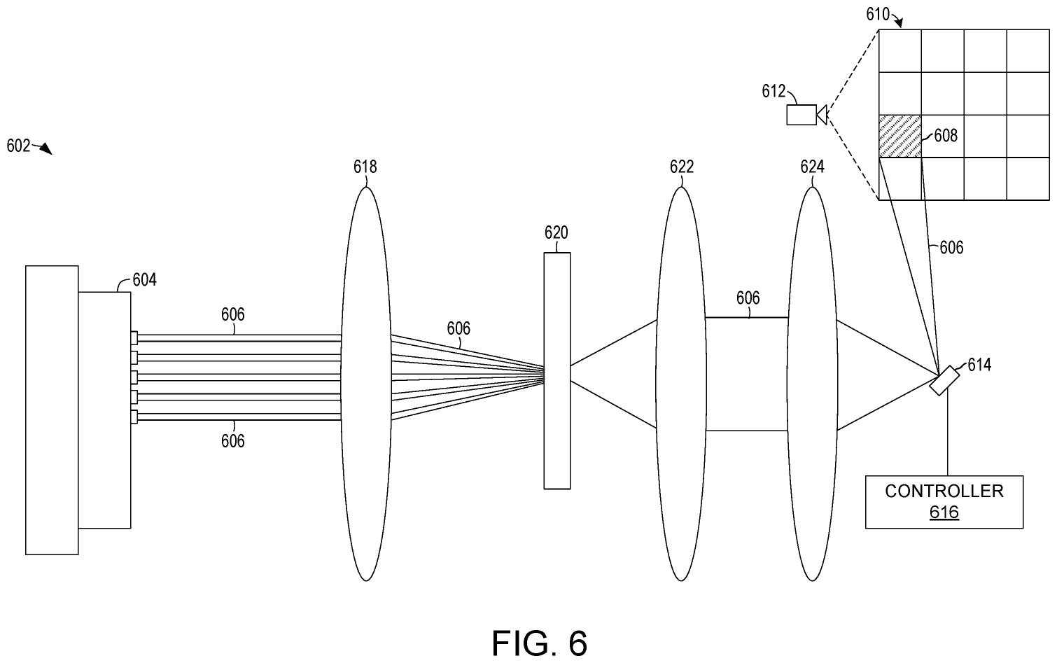

Depth imaging system 200 also includes a projector device 230 controlled via controller 208. The projector device 230 is configured to project electromagnetic radiation having any frequency detectable by ToF pixels 206 into an environment for depth imaging. The projector device 230 includes a light source such as a light-emitting diode (LED) and/or a laser diode (LD), as examples. As described in more detail below, the projector device 230 further includes a scanning mirror device configured to direct the electromagnetic radiation in a predetermined pattern, such as a raster pattern, to scan the environment. The sensor array 204 is configured to sample light from the light source 230 as reflected off subject 220 and back to the ToF camera 202. The round-trip travel time of the light reflected off the subject 220 is used to obtain a depth value (e.g., a distance between the ToF depth sensing system 200 and the subject 220) for each pixel. A more detailed example of a projector suitable for use as projector device 230 is described below with regard to FIG. 6.

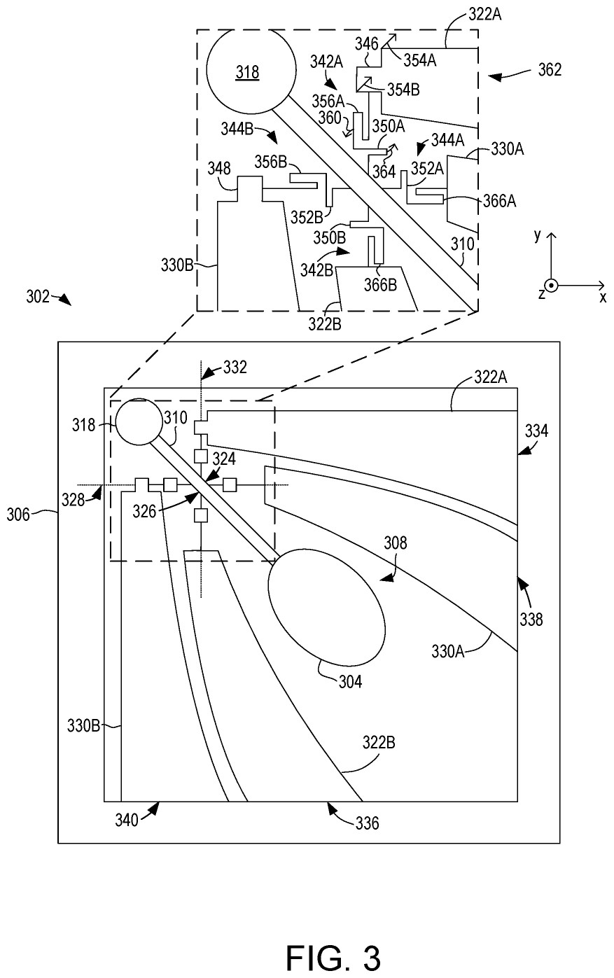

FIG. 3 shows an example of a scanning mirror device 302. The scanning mirror device 302 is an example of a scanning mirror device that may be used with projector device 230 of FIG. 2. The scanning mirror device 302 comprises a mirror 304 configured to reflect incident electromagnetic radiation, such as visible light, infrared light, or microwave radiation, in a controllable direction.

The mirror 304 is located within an aperture 308 in a center region of a frame 306 of the scanning mirror device 302. As described in more detail below, the location of the mirror 304 within the center region of the aperture 308 enables other components of the scanning mirror device 302 (e.g. actuators) to be arranged around the mirror 304. Such a configuration may occupy less space than some other possible configurations of the scanning mirror device.

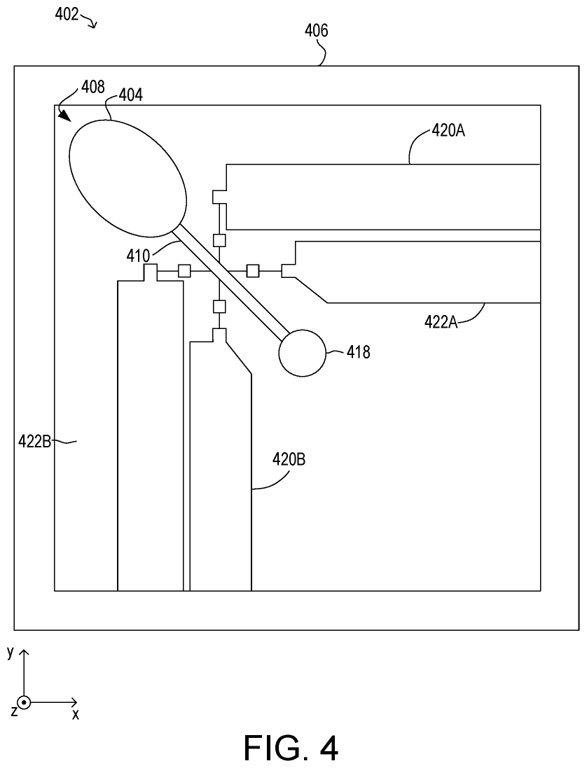

In other examples, a mirror may be located at any other suitable region of the scanning mirror device. FIG. 4 shows another example of a scanning mirror device 402. Like the scanning mirror device 302 of FIG. 3, the scanning mirror device 402 includes a mirror 404. However, in FIG. 4, the mirror 404 is located at a corner of an aperture 408 within a frame 406 of the scanning mirror device 402. Placing the mirror outside of the center region, as illustrated in FIG. 4, may provide for different design possibilities than placing the mirror inside of the center region, as illustrated in FIG. 3. For example, a mirror positioned outside of a center region may be configured with relatively larger dimensions (e.g., larger actuators or a larger mirror), and/or may be configured with different properties (e.g., a different resonant mode or frequency than the scanning mirror device 302).

Referring again to FIG. 3, the mirror 304 is disposed on a mirror support 310. In the depicted example, the mirror support 310 takes the form of a bar, but may take other forms in other examples. As described in more detail below, the mirror support 310 couples the mirror 304 to a plurality of actuators that are operatively configured to move the mirror 304.

In the depicted example, the mirror support 310 is oriented diagonally with respect to the sides of the frame 306 of the scanning mirror device 302. The mirror support 310 extends from a corner of the aperture 308 towards the center region of the aperture 308. The scanning mirror device 302 further comprises a counterweight 318 disposed on the mirror support 310 opposite the mirror 304. The counterweight 318 may help, for example, to prevent weight of the mirror 304 from biasing the mirror support 310 out of the XY plane. The counterweight 318 also may help to prevent rotation of the mirror from coupling to linear acceleration, stabilizing the mirror.

The counterweight 318 of the scanning mirror device 302 is disposed on the mirror support 310 at an end of the mirror support 310 closest to the frame 306. In other examples, the counterweight 318 may be located at any other suitable position. For example, the scanning mirror device 402 of FIG. 4 includes a counterweight 418 located at a center region of the frame 406, where the counterweight 418 is centered within the aperture 408.

In other examples, the mirror support 310 of FIG. 3 may be positioned at any other suitable location within the scanning mirror device 302 (e.g., at the center region 316). Further in other examples, the mirror support 310 further may have any other suitable orientation. For example, the mirror support 310 may be oriented parallel to one or more sides of the frame. This may allow the scanning mirror device to accommodate other components having different dimensions than the components depicted in the example of FIG. 3, and/or provide the scanning mirror device with alternative properties (e.g., a different resonant mode or frequency than the scanning mirror device 302).

The scanning mirror device 302 further comprises a first pair of actuators comprising a first actuator 322A and a second actuator 322B. The first actuator 322A is positioned on a first side 324 of the mirror support 310 and the second actuator 322B is positioned on a second side 326 of the mirror support 310 opposite the first side 324 of the mirror support 310. The first actuator 322A and the second actuator 322B are connected to the mirror support 310 along a first axis of rotation 328. The first actuator 322A is anchored to the frame 306 at a distal end 334 of the first actuator 322A opposite the mirror support 310, and the second actuator 322B is anchored to the frame 306 at a distal end 336 of the second actuator 322B opposite the mirror support 310. In some examples, the first actuator 322A and the second actuator 322B each comprises a piezoelectric material that may be operated by applying a suitable voltage. The application of voltages may be controlled to rotate or tilt the mirror support 310 along the first axis of rotation 328.

The scanning mirror device 302 further includes a second pair of actuators comprising a third actuator 330A and a fourth actuator 330B. The third actuator 330A is positioned on the first side 324 of the mirror support 310. The fourth actuator 330B is positioned on the second side 326 of the mirror support 310. The third actuator 330A and the fourth actuator 330B are connected to the mirror support 310 along a second axis of rotation 332. In some examples, the third actuator 330A is anchored to the frame 306 at a distal end 338 of the third actuator 330A opposite the mirror support 310, and the fourth actuator 330B is anchored to the frame 306 at a distal end 340 of the fourth actuator 330B opposite the mirror support 310. In this manner, and as described in more detail below, the third actuator 330A and the fourth actuator 330B are operatively configured to tilt the mirror 304 about the Y axis. In some examples, the third actuator 330A and the fourth actuator 330B each comprises a piezoelectric material that may be operated by applying a suitable voltage. The application of voltages may be controlled to tilt the mirror support 310 along the second axis of rotation 332.

The voltage applied to operate the third actuator 330A and the fourth actuator 330B may be the same or different than the voltage applied to operate the first actuator 322A and the second actuator 322B. In some examples, the third actuator 330A and the fourth actuator 330B are operated to move with half of a maximum displacement as the first actuator 322A and the second actuator 322B. This may reduce complexity of the scanning mirror device in examples where less displacement is required along one of two axes (e.g., to perform a raster scan of a rectangular area in which one side is shorter than another side).

In some examples, the first axis of rotation 328 and the second axis of rotation 332 are offset from the center region of the aperture 308. This enables the actuators 322A, 322B, 330A, 330B to be arranged around the mirror 304 and connect to the mirror support 310 near the corner 314. As a result, the scanning mirror device 302 may occupy less space than other arrangements of the actuators 322A, 322B, 330A, 330B and the mirror 304.

The first axis of rotation 328 is, in some examples, orthogonal to the second axis of rotation 332. For example, the first axis of rotation 328 depicted in the example of FIG. 3 is parallel to the X-axis (e.g., the first actuator 322A and the second actuator 322B are operatively configured to rotate the mirror around the X-axis). The second axis of rotation 332 is parallel to the Y-axis (e.g., the third actuator 330A and the fourth actuator 330B are operatively configured to rotate the mirror around the Y-axis). In this manner, the actuators may control the mirror to scan in the X-axis and Y-axis directions (e.g., in a raster pattern) with less off-axis motion than the use of non-orthogonal axes. In other examples, the first axis of rotation and the second axis of rotation have any other suitable relative orientations.

The scanning mirror device 400 of FIG. 4 similarly includes a first pair of actuators 420A, 420B connected to a mirror support 410 along a first axis of rotation, and a second pair of actuators 422A, 422B connected to the mirror support 410 along a second axis of rotation. Like the actuators 322A, 322B, 330A, 330B of FIG. 3, the actuators 420A, 420B, 422A, 422B of FIG. 4 have diagonal mirror symmetry with respect to the mirror support 410. Such a configuration may occupy less space than some other possible configurations of the scanning mirror device, such as configurations featuring asymmetrical orientations of the actuators.

Each of the actuators 322A, 322B, 330A, 330B in FIG. 3, and each of the actuators 420A, 420B, 422A, 422B in FIG. 4 may comprise a piezoelectric actuator. Motion of a piezoelectric actuator is proportional to a magnitude of an electric field applied across a piezoelectric material layer of the actuator, which induces mechanical changes in the piezoelectric material layer. Thus, referring to FIG. 3, applying a higher voltage to the piezoelectric actuator results in greater displacement of the mirror 304 than applying a lower voltage. In this manner, actuators can be used to tilt the mirror to target orientations by controlling the voltages applied to the actuators. Any suitable piezoelectric material may be used. Examples include lead zirconate titanate (PZT), Nb-doped PZT (PNZT), and aluminum scandium nitride. In other examples, one or more of actuators 322A, 322B, 330A, 330B additionally or alternatively may include any other suitable type of actuator(s). Other examples of suitable actuators include, but are not limited to, one or more electrostatic actuators, magnetic (e.g., Lorentz force) actuators, or thermal (e.g., bimetallic) actuators.

Continuing with FIG. 3, each actuator is connected to the mirror support by a connector. For example, the first actuator 322A is connected to the mirror support 310 by connector 342A. The second actuator 322B is connected to the mirror support 310 by connector 342B. The third actuator 330A is connected to the mirror support 310 by connector 344A, and the fourth actuator 330B is connected to the mirror support 310 by connector 344B. Connectors 342A, 342B, 344A, and 344B are shown schematically in FIG. 3.

Inset 362 shows the connectors 342A, 342B, 344A and 344B in more detail. Functional aspects of each connector 342A, 342B, 344A, and 344B are illustrated schematically by blocks located along each connector. Each connector includes a flexure portion located proximate to the mirror support. Outer actuators 322A and 330B further include an actuator portion, in the form of a tab (346 and 348, respectively) extending from each actuator and connecting the actuator to a respective connector. The connector 342A includes a torsional portion 356A and a flexure portion 350A between the tab 346 of the actuator 322A and the mirror support 310. The torsional portion 356A enables the connector 342A to twist about the Y-axis, as indicated by arrow 360. The flexure portion 350A enables the connector 342 to bend around the X-axis, as indicated by arrow 364. As described in more detail below, the torsional portion 356A and the flexure portion 350A enable the connector 342 to transfer motion of the actuator 322A to the mirror support 310 while providing sufficient flexibility in a torsional yielding mode (e.g., as indicated by arrow 360) and a flexural yielding mode (e.g., as indicated by arrow 364) to prevent the actuator 322A from straining the connector 342A. Similarly, the connector 344B includes a torsional portion 356B and a flexure portion 352B between the tab 348 and the mirror support 310. The connector 342B includes torsional portion 366B and a flexure portion 350B between the actuator 322B and the mirror support 310, and the connector 344A includes a torsional portion 366A and a flexure portion 352A between the actuator 330A and the mirror support 310.

The torsional portion and the flexure portion of each connector is configured to be comparably rigid with respect to linear bending and rotational torsion. For example, the rigidity of the flexure portion with respect to linear and torsional bending may be represented by bending and torsional moduli of the connector. Those two yielding modes are engineered to be at comparable stiffness levels at mirror actuation. When actuating the mirror to tilt along the x axis, connectors 344A and 344B serve as actuation force couplers in a linear bending mode, and connectors 342A and 342B serve as mirror supports in a torsional yielding mode. For y-axis tilt, the functions of the connectors are inverted. When actuating to the +x +y corner, the connector bending and torsional modes are mixed and simultaneously activated. The frequency response range may be increased by utilizing stiffer connector flexures.

Referring to the connector 342A, upward actuator motion of the actuator 322A is shown by arrow 354A. The tab 346 connected to the connector 342A is relatively rigid in the direction of motion of the actuator 322A, and thus moves in a similar direction and with a similar magnitude, as indicated by arrow 354B. The torsional portion 356A is oriented in a different direction than the actuator 322, and yields in direct bending but also in a torsional mode due to the nature of the connection symmetry experienced during the actuator motion. In response, as indicated by arrow 360, the torsional portion 356A undergoes some torsional deformation, while also transferring some of the linear motion of the actuator in the upward direction. This causes the mirror support to tilt towards the negative Y-axis direction (or rotate along the x-axis). This tilt causes torsional yielding at the connectors 344A and 344B contemporaneously with the tilting of the mirror support.

Scanning mirror device 302 may be formed in any suitable manner. In some examples, the scanning mirror device is formed from a silicon-on-insulator substrate. Such a substrate comprises a first silicon layer, a silicon oxide intermediate layer, and a second silicon layer. The first silicon layer may be referred to as a handle layer, and the second silicon layer may be referred to as a device layer. In such examples, the mirror 304, the mirror support 310, the counterweight 318, the actuators 322A, 322B, 330A, 330B, and the connectors 342A, 342B, 344A, 344B may be formed from device-layer silicon, with the intermediate oxide layer and the handle layer being etched away. Silicon is compliant and has a fracture strength in the range of 1-10 GPa. Thus, such a construction may enables the scanning mirror device to undergo actuation without damaging the connectors. Regions for mounting the scanning mirror device to an underlying structure (e.g., a circuit board) may comprise the handle layer and oxide layer to provide vertical relief for the mirror relative to the underlying circuit board or other structure. In other examples, a scanning mirror device may be formed from any other suitable type of substrate. Examples include silicon wafers.

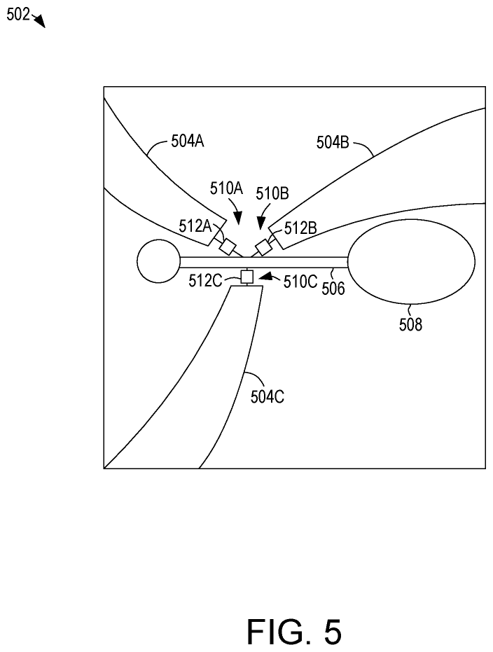

In the examples of FIGS. 3 and 4, the scanning mirror devices 300, 400 each comprises two pairs of actuators. In other examples, the scanning mirror device may include any other suitable number of and arrangement of actuators. FIG. 5 shows an example of a scanning mirror device 502 that includes a first actuator 504A connected to the mirror support 506 at a first angle relative to the mirror support, a second actuator 504B connected to the mirror support 506 at a second angle relative to the mirror support, and a third actuator 504C connected to the mirror support 506 at a third angle relative to the mirror support. The first actuator 504A is connected to the mirror support 506 via a first connector 510A. The second actuator 504B is connected to the mirror support 506 via a second connector 510B. The third actuator 504C is connected to the mirror support 506 via a third connector 510C. Each of the connectors 510A-510C may be analogous to the connectors 342A, 342B, 344A, 344B. For example, the first connector 510A includes a first flexure portion 512A, the second connector 510B includes a second flexure portion 512B, and the third connector 510C includes a third flexure portion 512C. This enables each connector to have sufficient strength and rigidity to transfer motion of the actuators to tilt the mirror, yet also have sufficient flexibility to prevent the actuators from exceeding subjecting the connector to forces that exceed a yield strength or fracture strength of the connector.

The first actuator 504A, the second actuator 504B, and the third actuator 504C may be controlled to tilt the mirror 508 in a variety of directions. In some examples, the first actuator 504A, the second actuator 504B, and the third actuator 504C are oriented approximately 120 degrees apart. In other examples, the actuators 504A, 504B and 504C may have any other suitable relative orientations. The three-actuator configuration of FIG. 5 may allow for a more compact construction than configurations with a greater number of actuators.

A scanning mirror system according to the present disclosure may be configured to scan at any suitable frame rate. In some examples, the scanning mirror system is actuated to hold the mirror at a static tilt (e.g., in a servo-like operation). In other examples, the scanning mirror system is actuated to tilt the mirror in an oscillatory mode at a suitable frequency. In some examples, a scanning mirror system according to the present disclosure is configured to perform a raster scan at a frame rate of up to 100 Hz, In other examples, a scanning mirror system according to the present disclosure may be configured to perform the raster scan at a rate of up to 1000 Hz. In yet other examples, a scanning mirror system according to the present disclosure may be configured to perform the raster scan at a rate of greater than 1000 Hz, or less than 100 Hz. It will also be appreciated that the scanning mirror system may be actuated to tilt the mirror in any other suitable pattern (e.g., a predetermined or dynamically adjusted pattern provided by a user of the scanning mirror system).

FIG. 6 shows an example of a ToF projector device 602 that may comprise a scanning mirror device according to the present disclosure. The ToF projector device 602 is an example of the projector device 230 of FIG. 2. The ToF projector device 602 comprises a light source 604, such as a vertical cavity surface-emitting laser (VCSEL) comprising a plurality of laser cavities each operatively configured to emit light 606. As described in more detail below, the light 606 illuminates a portion 608 of a field of view 610 of a zoned ToF camera 612. The zoned ToF camera 612 images the portion 608 illuminated by the light 606 to determine a depth value for the portion 608 of the field of view 610.

The ToF projector device 602 further comprises a scanning mirror device 614 controllable by a controller 616 to project the light 606 from the light source 604 into an environment. The scanning mirror device 614 optionally receives the light 606 via a focusing lens 618, a diffusing lens 620, and/or relay lenses 622, 624. The scanning mirror device 302 of FIG. 3, the scanning mirror device 402 of FIG. 4, or the scanning mirror device 502 of FIG. 5 are examples of the scanning mirror device 614. The controller 616 may comprise a computing system. Additional aspects of the controller 616 are described in more detail below with reference to FIG. 7.

The scanning mirror device 614 is configured to direct the light 606 to the portion 608 of the field of view 610 of the camera 612. The scanning mirror device 614 is further configured to move the light 606 in a predetermined pattern (e.g., in a raster scanning pattern) to scan the field of view 610. In some examples, the scanning mirror device 614 is configured to conduct a raster scan of the field of view 610 at a frame rate of up to 100-1000 Hz. In other examples, the scanning mirror device 614 is configured to scan the field of view 610 at a frame rate of greater than 1000 Hz, or less than 100 Hz. By imaging each illuminated portion 608 of the field of view 610, the camera 612 may build a three-dimensional depth image of the field of view 610. Additionally, using a zoned ToF approach to image the field of view 610 enables the depth image to be constructed using a relatively low-intensity light source 604 to illuminate a portion of the field of view, rather than using a higher-intensity light source that is projected across a larger portion of the field of view. This enables the ToF projector device 602 to occupy less space and consume less power than other ToF depth sensing devices.

In some examples, the scanning mirror device 614 is additionally or alternatively configured to serve as a microwave reflector. For example, the scanning mirror device 614 may project microwaves having frequencies in the range of 0.1 GHz to 1000 GHz into the environment in a predetermined pattern, similar to the light 606, which may be used by the camera 612 (or a separate microwave detector) to obtain a microwave image of the environment. In other examples, the microwaves may have frequencies in the range of 0.3 GHz to 600 GHz. In yet other examples, the microwaves may have frequencies in the range of 0.3 GHz to 300 GHz. The resiliency of microwaves to weather conditions and lighting, and their ability to pass through many obstacles, may result in more reliable ToF depth mapping and/or gesture detection than using other electromagnetic spectra.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 7 schematically shows a non-limiting embodiment of a computing system 700 that can enact one or more of the methods and processes described above. Computing system 700 is shown in simplified form. The devices 100A-D described above and illustrated in FIG. 1, the controller 208 described above and illustrated in FIG. 2, and the controller 616 described above and illustrated in FIG. 6 are examples of the computing system 700. Components of the computing system 700 may be instantiated in one or more personal computers, server computers, tablet computers, home-entertainment computers, network computing devices, video game devices, mobile computing devices, mobile communication devices (e.g., smart phone), wearable computing devices such as smart wristwatches and head mounted augmented reality devices, and/or other computing devices.

Computing system 700 includes a logic processor 702 volatile memory 704, and a non-volatile storage device 706. Computing system 700 may optionally include a display subsystem 708, input subsystem 710, communication subsystem 712, and/or other components not shown in FIG. 7.

Logic processor 702 includes one or more physical devices configured to execute instructions. For example, the logic processor may be configured to execute instructions that are part of one or more applications, programs, routines, libraries, objects, components, data structures, or other logical constructs. Such instructions may be implemented to perform a task, implement a data type, transform the state of one or more components, achieve a technical effect, or otherwise arrive at a desired result.

The logic processor may include one or more physical processors (hardware) configured to execute software instructions. Additionally or alternatively, the logic processor may include one or more hardware logic circuits or firmware devices configured to execute hardware-implemented logic or firmware instructions. Processors of the logic processor 702 may be single-core or multi-core, and the instructions executed thereon may be configured for sequential, parallel, and/or distributed processing. Individual components of the logic processor optionally may be distributed among two or more separate devices, which may be remotely located and/or configured for coordinated processing. Aspects of the logic processor may be virtualized and executed by remotely accessible, networked computing devices configured in a cloud-computing configuration. In such a case, these virtualized aspects are run on different physical logic processors of various different machines, it will be understood.

Volatile memory 704 may include physical devices that include random access memory. Volatile memory 704 is typically utilized by logic processor 702 to temporarily store information during processing of software instructions. It will be appreciated that volatile memory 704 typically does not continue to store instructions when power is cut to the volatile memory 704.

Non-volatile storage device 706 includes one or more physical devices configured to hold instructions executable by the logic processors to implement the methods and processes described herein. When such methods and processes are implemented, the state of non-volatile storage device 706 may be transformed—e.g., to hold different data.

Non-volatile storage device 706 may include physical devices that are removable and/or built-in. Non-volatile storage device 706 may include optical memory (e.g., CD, DVD, HD-DVD, Blu-Ray Disc, etc.), semiconductor memory (e.g., ROM, EPROM, EEPROM, FLASH memory, etc.), and/or magnetic memory (e.g., hard-disk drive, floppy-disk drive, tape drive, MRAM, etc.), or other mass storage device technology. Non-volatile storage device 706 may include nonvolatile, dynamic, static, read/write, read-only, sequential-access, location-addressable, file-addressable, and/or content-addressable devices. It will be appreciated that non-volatile storage device 706 is configured to hold instructions even when power is cut to the non-volatile storage device 706.

Aspects of logic processor 702, volatile memory 704, and non-volatile storage device 706 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 708 may be used to present a visual representation of data held by non-volatile storage device 706. The visual representation may take the form of a graphical user interface (GUI). As the herein described methods and processes change the data held by the non-volatile storage device, and thus transform the state of the non-volatile storage device, the state of display subsystem 708 may likewise be transformed to visually represent changes in the underlying data. Display subsystem 708 may include one or more display devices utilizing virtually any type of technology. Such display devices may be combined with logic processor 702, volatile memory 704, and/or non-volatile storage device 706 in a shared enclosure, or such display devices may be peripheral display devices.

When included, input subsystem 710 may comprise or interface with one or more user-input devices such as a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition; as well as electric-field sensing componentry for assessing brain activity; and/or any other suitable sensor.

When included, communication subsystem 712 may be configured to communicatively couple various computing devices described herein with each other, and with other devices. Communication subsystem 712 may include wired and/or wireless communication devices compatible with one or more different communication protocols. As non-limiting examples, the communication subsystem may be configured for communication via a wireless telephone network, or a wired or wireless local- or wide-area network, such as a HDMI over Wi-Fi connection. In some embodiments, the communication subsystem may allow computing system 700 to send and/or receive messages to and/or from other devices via a network such as the Internet.

The following paragraphs discuss several aspects of the present disclosure. One aspect provides a scanning mirror device, comprising: a mirror disposed on a mirror support; a first pair of actuators comprising a first actuator and a second actuator, the first actuator positioned on a first side of the mirror support, the second actuator positioned on a second side of the mirror support opposite the first side of the mirror support, and the first actuator and the second actuator connected to the mirror support along a first axis of rotation; and a second pair of actuators comprising a third actuator and a fourth actuator, the third actuator positioned on the first side of the mirror support, the fourth actuator positioned on the second side of the mirror support, and the third actuator and the fourth actuator connected to the mirror support along a second axis of rotation.

Further to this aspect, in some examples, the mirror support is additionally or alternatively oriented diagonally with respect to a frame of the scanning mirror device.

Further to this aspect, in some examples, the mirror is additionally or alternatively located in a center region of a frame of the scanning mirror device.

Further to this aspect, in some examples, the scanning mirror device additionally or alternatively includes a counterweight disposed on the mirror support opposite the mirror.

Further to this aspect, in some examples, the counterweight is additionally or alternatively located in a center region of a frame of the scanning mirror device.

Further to this aspect, in some examples, the first axis of rotation and the second axis of rotation are additionally or alternatively offset from a center region of a frame of the scanning mirror device.

Further to this aspect, in some examples, the first axis of rotation is additionally or alternatively orthogonal to the second axis of rotation.

Further to this aspect, in some examples, each actuator is additionally or alternatively connected to the mirror support by a connector, and the connector additionally or alternatively includes a torsional portion and a flexural portion between the actuator and the mirror support.

Further to this aspect, in some examples, the torsional portion is additionally or alternatively oriented in a different direction than the actuator.

Further to this aspect, in some examples, the torsional portion is additionally or alternatively configured to yield in a torsional mode in response to activation of the actuator.

Further to this aspect, in some examples, the scanning mirror device is additionally or alternatively formed from a silicon-on-insulator substrate.

Another aspect provides a time-of-flight device, comprising: a controller; a light source operatively configured to emit light; and a scanning mirror device controllable by the controller to project the light from the light source into an environment, the scanning mirror device comprising, a mirror disposed on a mirror support, the mirror operatively configured to receive the light from the light source and to reflect the light; a first pair of actuators comprising a first actuator and a second actuator, the first actuator positioned on a first side of the mirror support, the second actuator positioned on a second side of the mirror support opposite the first side of the mirror support, and the first actuator and the second actuator connected to the mirror support along a first axis of rotation; and a second pair of actuators comprising a third actuator and a fourth actuator, the third actuator positioned on the first side of the mirror support, the fourth actuator positioned on the second side of the mirror support, and the third actuator and the fourth actuator connected to the mirror support along a second axis of rotation.

Further to this aspect, in some examples, the mirror support is additionally or alternatively oriented diagonally with respect to a frame of the scanning mirror device.

Further to this aspect, in some examples, the time-of-flight device additionally or alternatively includes a counterweight disposed on the mirror support opposite the mirror.

Further to this aspect, in some examples, the first axis of rotation and the second axis of rotation are additionally or alternatively offset from a center of the scanning mirror device.

Further to this aspect, in some examples, the first axis of rotation is additionally or alternatively orthogonal to the second axis of rotation.

Further to this aspect, in some examples, the time-of-flight projector additionally or alternatively comprises a zoned time-of-flight projector.

Another aspect provides a scanning mirror device, comprising: a mirror disposed on a mirror support; a first actuator connected to the mirror support at a first angle relative to the mirror support; a second actuator connected to the mirror support at a second angle relative to the mirror support; and a third actuator connected to the mirror support at a third angle relative to the mirror support.

Further to this aspect, in some examples, the mirror is additionally or alternatively located in a center region of a frame of the scanning mirror device.

Further to this aspect, in some examples, the first angle, the second angle, and the third angle are additionally or alternatively oriented approximately 120 degrees apart.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A scanning mirror device, comprising:
a mirror disposed on a mirror support;
a first pair of actuators comprising a first actuator and a second actuator, the first actuator positioned on a first side of the mirror support, the second actuator positioned on a second side of the mirror support opposite the first side of the mirror support, and the first actuator and the second actuator connected to the mirror support along a first axis of rotation; and
a second pair of actuators comprising a third actuator and a fourth actuator, the third actuator positioned on the first side of the mirror support, the fourth actuator positioned on the second side of the mirror support, and the third actuator and the fourth actuator connected to the mirror support along a second axis of rotation.

2. The scanning mirror device of claim 1, wherein the mirror support is oriented diagonally with respect to a frame of the scanning mirror device.

3. The scanning mirror device of claim 1, wherein the mirror is located in a center region of a frame of the scanning mirror device.

4. The scanning mirror device of claim 1, further comprising a counterweight disposed on the mirror support opposite the mirror.

5. The scanning mirror device of claim 4, wherein the counterweight is located in a center region of a frame of the scanning mirror device.

6. The scanning mirror device of claim 1, wherein the first axis of rotation and the second axis of rotation are offset from a center region of a frame of the scanning mirror device.

7. The scanning mirror device of claim 1, wherein the first axis of rotation is orthogonal to the second axis of rotation.

8. The scanning mirror device of claim 1, wherein each actuator is connected to the mirror support by a connector, and wherein the connector includes a torsional portion and a flexural portion between the actuator and the mirror support.

9. The scanning mirror device of claim 8, wherein the torsional portion is oriented in a different direction than the actuator.

10. The scanning mirror device of claim 9, wherein the torsional portion is configured to yield in a torsional mode in response to activation of the actuator.

11. The scanning mirror device of claim 1, wherein the scanning mirror device is formed from a silicon-on-insulator substrate.

12. A time-of-flight device, comprising:
a controller;
a light source operatively configured to emit light; and
a scanning mirror device controllable by the controller to project the light from the light source into an environment, the scanning mirror device comprising,
a mirror disposed on a mirror support, the mirror operatively configured to receive the light from the light source and to reflect the light;
a first pair of actuators comprising a first actuator and a second actuator, the first actuator positioned on a first side of the mirror support, the second actuator positioned on a second side of the mirror support opposite the first side of the mirror support, and the first actuator and the second actuator connected to the mirror support along a first axis of rotation; and
a second pair of actuators comprising a third actuator and a fourth actuator, the third actuator positioned on the first side of the mirror support, the fourth actuator positioned on the second side of the mirror support, and the third actuator and the fourth actuator connected to the mirror support along a second axis of rotation.

13. The time-of-flight device of claim 12, wherein the mirror support is oriented diagonally with respect to a frame of the scanning mirror device.

14. The time-of-flight device of claim 12, further comprising a counterweight disposed on the mirror support opposite the mirror.

15. The time-of-flight device of claim 12, wherein the first axis of rotation and the second axis of rotation are offset from a center of the scanning mirror device.

16. The time-of-flight device of claim 12, wherein the first axis of rotation is orthogonal to the second axis of rotation.

17. The time-of-flight device of claim 12, wherein the time-of-flight projector comprises a zoned time-of-flight projector.

18. A scanning mirror device, comprising:
a mirror disposed on a mirror support;
a first actuator connected to the mirror support at a first angle relative to the mirror support;
a second actuator connected to the mirror support at a second angle relative to the mirror support; and
a third actuator connected to the mirror support at a third angle relative to the mirror support.

19. The scanning mirror device of claim 18, wherein the mirror is located in a center region of a frame of the scanning mirror device.

20. The scanning mirror device of claim 18, wherein the first angle, the second angle, and the third angle are oriented approximately 120 degrees apart.
